(19) United States
(12) Patent Application Publication
(10) Pub. No.: US 2026/0206276 A1
(43) Pub. Date: Jul. 16, 2026

(54) SEMICONDUCTOR DEVICE AND MANUFACTURING METHOD THEREOF

(71) Applicant: DYNAX SEMICONDUCTOR, INC., Kunshan (CN)

(72) Inventors: Yuan LI, Kunshan (CN); Yi PEI, Kunshan (CN); Pengyu HAN, Kunshan (CN); Xiang WANG, Kunshan (CN)

(21) Appl. No.: 19/137,153

(22) PCT Filed: Nov. 13, 2023
(86) PCT No.: PCT/CN2023/131290

§ 371 Date: Jun. 9, 2025

(30) Foreign Application Priority Data
Dec. 9, 2022 (CN) 202211577602.4

(51) Int. Cl. H10D 64/00; H10D 30/01; H10D 30/47; H10D 62/10

(52) U.S. Cl. CPC H10D 64/111; H10D 30/015; H10D 30/475; H10D 62/102

(57) ABSTRACT

Embodiments of the present disclosure provide a semiconductor device and a manufacturing method thereof, the semiconductor device including a field plate body portion and at least one field plate end portion extending to a passive region, by setting an extending width of a first field plate end portion and/or a second field plate end portion of the field plate, which are at least located at the passive region, to be greater than an extending width of the field plate body portion, it facilitates improving the reliability and stability of the field plate, and by reserving a certain distance between an active region and a first boundary line of the first field plate end portion and/or the field plate end portion, the capacitance problem between the gate-source electrodes is reduced while regulating the distribution of the electric field near the gate at the boundary of the active region.

### CROSS REFERENCE TO RELATED APPLICATIONS

This patent application is a National Stage Entry of PCT/CN2023/131290 filed on Nov. 13, 2023, which claims the benefit and priority of Chinese Patent Application No. 202211577602.4 filed on Dec. 9, 2022, the disclosures of which are incorporated by reference herein in their entirety as part of the present application.

### BACKGROUND

Embodiments of the present disclosure relate to the field of semiconductor technology, and in particular to a semiconductor device and a manufacturing method thereof.

Gallium nitride (GaN), as a semiconductor material, due to its features such as wide forbidden band, high electron mobility, high breakdown field strength, good thermal conductivity, and due to it has a strong spontaneous and piezoelectric polarization effect, compared to first- and second-generation semiconductor materials, it is more suitable for manufacturing high-frequency, high-voltage and high-temperature-resistant high-power electronic devices, and it has obvious advantage especially in the field of RF and power supply.

Currently, 5G communication has high requirements for the bandwidth and high-frequency performance of a semiconductor device, while design and process flow for the structure of a gate has a close relationship with the frequency characteristics of the semiconductor device, the dimension of the gate directly affects the operating frequency of the semiconductor device, the position of the gate and its relationship with the neighboring components directly affect the performance and reliability of the device. Therefore, during the design and manufacture of the semiconductor device, the design of the gate is particularly important, and plays a key role in the reliability and stability of the operating performance of the semiconductor device.

Therefore, how to further enhance the reliability of a gate of a semiconductor device, achieve a gate design that has reliable performance of the semiconductor device, and enable large-scale commercial production and manufacture, has become an urgent problem.

### BRIEF DESCRIPTION

In view of this, embodiments of the present disclosure provide a semiconductor device and a method of manufacturing the same to provide a semiconductor device with high gate reliability and stable semiconductor device performance, which can be used in fields such as radio frequency (RF) microwave and power electronics.

In a first aspect, embodiments of the present disclosure provide a semiconductor device including an active region and a passive region surrounding the active region, the semiconductor device further including:
a substrate;
a multi-layer semiconductor layer located at one side of the substrate;
a source, a gate, and a drain located at a side of the multi-layer semiconductor layer away from the substrate, the gate being located between the source and the drain; and
a field plate located between the source and the drain, along a first direction, the field plate includes a field plate body portion and a field plate end portion, at least one of the field plate end portions extending to the passive region, the first direction being parallel to an extending direction of the source, the gate, and the drain;
wherein, an extending width of the field plate body portion in a second direction remains constant, at least one of the field plate end portions extending from the field plate body portion toward the gate in the second direction, an extending width of the at least one of the field plate end portions in the second direction being greater than the extending width of the field plate body portion, and the second direction being parallel to a direction from the source to the drain.

The field plate end portion may be in zero contact with each of the source, the gate, and the drain.

Along the second direction and within the passive region, a projection of the field plate end portion on the substrate may partially overlap with a projection of the gate on the substrate, and the projection of the field plate end portion on the substrate does not overlap with a projection of the source on the substrate.

Along the first direction, the field plate end portion may include a first boundary line and a second boundary line, the second boundary line being located at a side of the first boundary line away from the active region, and the first boundary line and the second boundary line of at least one of the field plate end portions are both located within the passive region.

A distance between the first boundary line of at least one of the field plate end portions and an adjacent active region may be d, wherein d≤5 μm is satisfied.

The field plate end portion may include a first field plate end portion and a second field plate end portion, a distance between the first boundary line of the first field plate end portion and an adjacent active region is d1, and a distance between the first boundary line of the second field plate end portion and an adjacent active region is d2, wherein d1=d2 is satisfied.

The gate further may include a first end portion of the gate, an intermediate portion of the gate, and a second end portion of the gate, the first end portion of the gate and/or the second end portion of the gate being located within the passive region, wherein the second boundary line of the field plate end portion is located between an adjacent first end portion of the gate and/or an adjacent second end portion of the gate and the active region.

The second boundary line of the field plate end portion may be located at a side, which is closer to the active region, of a dividing line between the adjacent first end portion of the gate and/or the adjacent second end portion of the gate and the intermediate portion.

The dividing line between the first end portion of the gate and/or the second end portion of the gate and the intermediate portion may be at a distance of b from the second boundary line of the adjacent field plate end portion, and b<3 μm is satisfied.

The field plate end portion may include a first field plate end portion and a second field plate end portion, the second boundary line of the first field plate end portion is at a distance of b1 from the dividing line between the adjacent first end portion of the gate and the intermediate portion, and the second boundary line of the second field plate end portion is at a distance of b2 from the dividing line between the adjacent second end portion of the gate and the intermediate portion, wherein b1=b2 is satisfied.

A difference between a width of the field plate end portion extending toward the gate and the extending width D of the field plate body portion may be L, and L≥0.5*D is satisfied.

The field plate end portion further may include an extension terminating line, the extension terminating line being located at a side of the gate away from the field plate.

The field plate further may include a field plate connecting portion, the field plate connecting portion is located at the active region and extends from the field plate body toward the source until it contacts the source, and the field plate body portion, the field plate end portion, and the field plate connecting portion are integrally formed.

In a second aspect, embodiments of the present disclosure also provide a method of manufacturing a semiconductor device, the manufacturing method including:
providing a substrate;
fabricating a multi-layer semiconductor layer at one side of the substrate;
fabricating a source, a gate, and a drain at a side of the multi-layer semiconductor layer away from the substrate, the gate being located between the source and the drain;
fabricating a dielectric layer at a side of the gate away from the substrate; and
fabricating a field plate near the gate located at a side of the dielectric layer away from the substrate, the field plate includes a field plate body portion, and at least one field plate end portion extending to a passive region, the field plate end portion extending from the field plate body portion toward the gate, and an extending width of the field plate end portion is greater than an extending width of the field plate body portion.

A portion of the source may be exposed before fabricating the field plate, and the structure of the field plate is formed integrally in a same process step.

The semiconductor device and the method for manufacturing the same provided by embodiments of the present disclosure, by setting an extending width of a first field plate end portion and/or a second field plate end portion of the field plate, which are at least located at the passive region, to be greater than an extending width of the field plate body portion, improve the reliability and stability of the structure of the field plate, by reserving a certain distance between an active region and a first boundary line of the first field plate end portion and/or the field plate end portion, and by setting a difference between the extending width of the field plate end portion and that of the field plate body portion to satisfy a certain relationship, reduce the capacitance problem between the gate-source electrodes while regulating the distribution of the electric field near the gate at the boundary of the active region, and further by setting a difference between the extending width of the field plate end portion and that of the field plate body portion to satisfy a certain relationship to reduce the stresses between the structures, improve the reliability and stability of the chip.

### BRIEF DESCRIPTION OF THE DRAWINGS

FIG. 1 is a schematic diagram of a top view structure of a semiconductor device provided by an embodiment of the present disclosure;

FIG. 2 is a schematic diagram of a top view structure of a semiconductor device provided by an embodiment of the present disclosure;

FIG. 3 is a schematic diagram of a top view structure of another semiconductor device provided by an embodiment of the present disclosure; and

FIG. 4 is a schematic diagram of a cross-sectional structure of a semiconductor device provided by an embodiment of the present disclosure.

### DETAILED DESCRIPTION

The present disclosure is described in further detail below in connection with the accompanying drawings and embodiments. It is to be understood that the specific embodiments described herein are for the purpose of explaining the present disclosure only and are not a limitation of the disclosure. It is also to be noted that, for ease of description, only portions related to the present disclosure are shown in the accompanying drawings, rather than the entire structure.

The technical solutions in embodiments of the present disclosure are described clearly and completely in conjunction with the accompanying drawings in the embodiments of the present disclosure. Based on the embodiments in the present disclosure, all other embodiments obtained by a person of ordinary skill in the art without making creative labor fall within the scope of protection of the present disclosure.

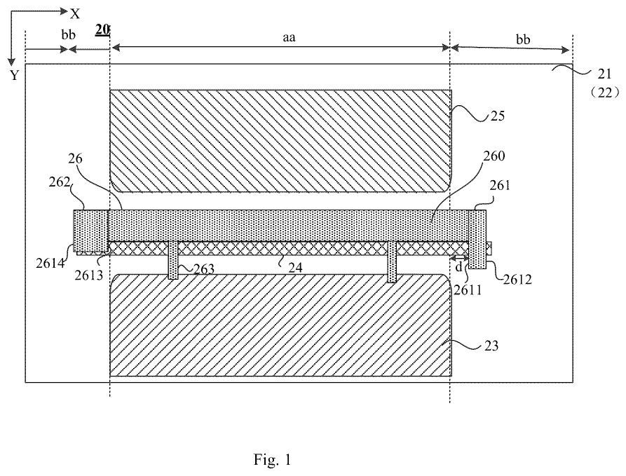

FIG. 1 is a schematic diagram of a structure of a semiconductor device provided by an embodiment of the present disclosure, as shown in FIG. 1, the semiconductor device 20 provided by the embodiment of the present disclosure includes an active region aa, and a passive region bb surrounding the active region aa, the semiconductor device 20 further includes:
a substrate 21;
a multi-layer semiconductor layer 22 located at one side of the substrate 21;
a source 23, a gate 24, and a drain 25 located at a side of the multi-layer semiconductor layer 22 away from the substrate 21, the gate 24 being located between the source 23 and the drain 25;
a field plate 26 located between the source 23 and the drain 25, wherein, along a first direction (X direction as shown in FIG. 1), the field plate 26 includes a field plate body portion 260 and at least one field plate end portion 261 extending to the passive region bb; and
a dielectric layer 27 located at a side of the multi-layer semiconductor layer 22 away from the substrate 21 and located between the gate 24 and the field plate 26;
wherein, along a second direction (Y-direction as shown in FIG. 1), an extending width of the field plate body portion 260 in the second direction remains constant and maintains a constant value of D; the field plate in the embodiment of the present disclosure includes at least one field plate end portion extending to the passive region, and the field plate end portion 261 in the present disclosure is illustrated by taking the first field plate end portion 261 as an example, wherein the field plate end portion 261 extends from the field plate body portion 260 towards the gate 24, and the extending width is greater than an extending width D of the field plate body portion 260; the field plate end portion 261 is in zero contact with each of the source 23, the gate 24, and the drain 25, and this structural design can increase the reliability and stability of the field plate 26. It is to be noted that, zero contact means that there is no direct contact between the field plate end portion 261 and any of the electrodes of the source 23, the gate 24 and the drain 25, which may be that there is a dielectric layer isolated therebetween, or that there is a certain separation distance therebetween.

The material of the substrate 21 may be formed from one or more of silicon, sapphire, silicon carbide, gallium arsenide, gallium nitride, diamond, or other materials suitable for growing gallium nitride.

The multi-layer semiconductor layer 22 is located at one side of the substrate 21, and specifically, the multi-layer semiconductor layer 22 may be a semiconductor material of group III-V compounds, and may be formed from one or more of gallium arsenide, aluminum gallium arsenide, gallium nitride, aluminum gallium nitride, or indium gallium nitride, for example. The active region aa may be understood as a region underneath which two-dimensional electron gas, electrons, or holes exist, and whose operating state and characteristics are affected by an external circuitry, and which is an active operating region of a semiconductor device.

Exemplarily, as shown in FIG. 1, the source 23, the gate 24, and the drain 25 extend in a first direction and are arranged along a second direction. Wherein, the source 23 and the drain 25 are both located within an active region aa, and the gate 24 includes a portion within the active region aa and a portion located within a passive region bb. Along the second direction, a projection of the field plate end portion 261 on the substrate 21 partially overlaps, within the passive region bb, with a projection of the gate 24 on the substrate 21, and the projection of the field plate end portion 261 on the substrate 21 does not overlap with a projection of the source 23 on the substrate 21, which can optimize the distribution of the electric field near the gate 24 located at the boundary between the active region and the passive region. It should be noted that, although the projection of the field plate end portion 261 on the substrate 21 partially overlaps, within the passive region bb, with the projection of the gate 24 on the substrate 21, a dielectric layer 27 is provided between the field plate end portion 261 and the gate 24, so that there is no contact between the field plate end portion 261 and the gate 24.

Specifically, as shown in FIG. 1, along the first direction, the field plate 26 sequentially includes a first field plate end portion 261, a field plate body portion 260, and a second field plate end portion 262, wherein at least a majority of the field plate body portion 260 is located within the active region aa, and an extending width of the field plate body portion 260 in the second direction is kept constant and maintained at a fixed value of D. As long as at least one of the first field plate end portion 261 and the second field plate end portion 262 meets the above requirements, the reliability of the field plate and the distribution of the electric field at the edge of the active region can both be improved. May be, along the first direction, the first field plate end portion 261 and the second field plate end portion 262 are provided at both ends of the field plate, respectively, and both extend toward the side of the gate 24, and the extending width is greater than the extending width D of the field plate body portion 260, which facilitates ensuring the stable radio frequency performance of the semiconductor device.

Further, as shown in FIG. 1, along the first direction, the field plate end portion includes a first boundary line and a second boundary line, the second boundary line being located at a side of the first boundary line away from the active region. Exemplarily, the first field plate end portion 261 includes a first boundary line 2611 and a second boundary line 2612, the second boundary line 2612 being located at a side of the first boundary line 2611 away from the active region aa. The first boundary line 2611 and the second boundary line 2612 of the first field plate end portion 261 may both be located within the passive region bb, which can regulate the distribution of the electric field of the passive region adjacent to the active region, and at the same time reduce the influence on the active region to reduce breakdown. Specifically, as shown in FIG. 1, the second field plate end portion 262 includes a first boundary line 2613 and a second boundary line 2614, and the second boundary line 2614 of the second field plate end portion 262 being located at a side of the first boundary line 2613 away from the active region aa. By simultaneously setting that the first boundary line 2611 and the second boundary line 2612 of the first field plate end portion 261 are both located within the passive region bb, and that the first boundary line 2613 and the second boundary line 2614 of the second field plate end portion 262 are both located within the passive region bb, it facilitates further ensuring the stable radio frequency performance of the semiconductor device.

Further, it has been found that along the first direction, the field plate end portion includes a first boundary line and a second boundary line, the second boundary line being located at a side of the first boundary line away from the active region. A distance between the first boundary line of at least one field plate end portion and an adjacent active region aa is set to d. When d is less than or equals to 5 μm, satisfying such a distance can avoid increasing the gate-source capacitance of the device; furthermore, the gate-source capacitance can be further reduced when d≤3 μm, and exemplarily, d can be 0.5 μm, 1 μm, 2 μm, 2.5 μm, and the like. When it has been satisfied that d is within a range of 0.2 μm to 2 μm, the gate-source capacitance of the semiconductor device can be reduced as much as possible while effectively regulating the distribution of the electric field at the boundary of the active region, so as to improve the performance stability of the device.

Specifically, a distance between the first boundary line 2611 of the first field plate end portion 261 and an adjacent active region aa is d1, wherein, when d1≤5 μm, for example when d1≤3 μm, the gate-source capacitance of the device at the side of the active region can be reduced and the distribution of the electric field of the gate at the boundary of the corresponding active region can be regulated. Further, in order to improve the reliability of the overall active region of the chip, while ensuring the distance between the first boundary line 2611 of the first field plate end portion 261 and the adjacent active region aa, the distance between the first boundary line 2613 of the second field plate end portion 262 and the adjacent active region aa is d2, and d2≤5 μm. It should be noted that, d1 and d2 only need to satisfy that d1≤5 μm and d2≤5 μm, and the values of d1 and d2 may be different, but in order to ensure the reliability of the chip as well as the stability of the RF performance, furthermore, while satisfying d1≤5 μm and d2≤5 μm, d1 is set to be equal to d2, so as to improve the overall reliability and stability of the device.

Further, as shown in FIG. 1, the field plate 26 further includes a field plate connecting portion 263, the field plate connecting portion 263 is located at the active region and extends from the field plate body portion 260 toward the source 23 until it contacts the source 23. A projection of the field plate connecting portion 263 on the substrate 21 overlaps with a projection of the source 23 on the substrate 21. The location and function of the field plate connecting portion 263 in the present disclosure are not the same as those of the field plate end portion 261, and the field plate connecting portion 263 mainly functions to electrically connect the field plate and the source 23, and due to their different locations and functions, it is possible to realize that the field plate body portion 260, the field plate end portion 261, and the field plate connecting portion 263 of the field plate 26 can be fabricated in a same process step, and that the field plate body portion 260, the field plate end portion 261 and the field plate connecting portion 263 are integrally formed, thereby reducing the process complexity and avoiding the need for opening holes for connection between the field plate 26 and the source 23.

In summary, the semiconductor device provided by embodiments of the present disclosure, by setting an extending width of a first field plate end portion and/or a second field plate end portion of the field plate, which are at least located at the passive region, to be greater than an extending width of the field plate body portion, and by reserving a certain distance between an active region and a first boundary line of the first field plate end portion and/or the field plate end portion, reduces the capacitance problem between the gate-source electrodes while regulating the distribution of the electric field near the gate at the boundary of the active region; and further improves the reliability and stability of the chip.

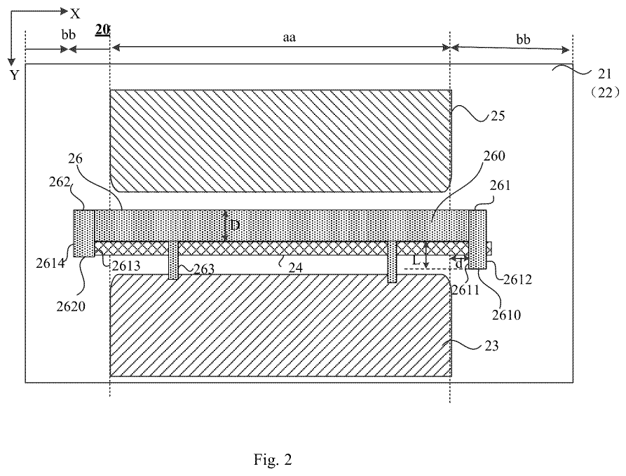

In another implementation, as shown in FIG. 2, the semiconductor device 20 provided by embodiments of the present disclosure includes that, the field plate end portion 261 further includes an extension terminating line 2610 extending toward the gate. A distance between the extension terminating line 2610 of the field plate end portion 261 extending toward the gate and the field plate body portion 260 may be L, or alternatively, a difference between the width of the field plate end portion 261 extending toward the gate and the extending width of the field plate body portion 260 is L, wherein, a difference between the extending width of the field plate end portion 261 and that of the field plate body portion 260 satisfies L≥0.5*D, which can effectively improve the structural stability and reliability of the field plate in the passive region, and when a difference between the extending width of the field plate end portion 261 and that of the field plate body portion 260 satisfies L≤10*D, it can further reduce the capacitance problem between the gate-source electrodes, improving the reliability and stability of the chip, wherein D is the extending width of the field plate body portion 260. Exemplarily, the difference L in extending width between the field plate end portion 261 and the field plate body portion 260 may be D, 1.5*D, 2*D, 2.5*D, 3*D, 3.5*D, 4*D, 4.5*D, 5*D, 6*D, and so on, and the specific values are not enumerated in the embodiments of the present disclosure, and it only needs to ensure that 0.5*D≤L≤10*D is satisfied, so as to realize that not only the reliability of the field plate in the passive region can be improved, but also the capacitance problem between the gate-source electrode can be reduced, thereby improving the reliability and stability of the chip.

On the basis of the above embodiments, as shown in FIG. 2, since the relative position of the field plate 26 and the gate 24 will change with different device structures, the extending width of the field plate body portion 260 and the position relative to the gate 24 will also change according to the different devices; exemplarily, along the second direction (the Y-direction as shown in FIG. 2), the field plate 26 is located between the drain 25 and the source 23, wherein, the body portion 260 of the field plate 26 is located between the drain 25 and the boundary line of the gate 24 that is close to the source 23, wherein, the projection of the body portion of the field plate 26 on the substrate 21 may or may not overlap with the projection of the gate 24 on the substrate 21. Therefore, it is also necessary to set that, along the second direction (the Y direction as shown in FIG. 2), the terminating line extending from the field plate end portion 261 is located at a side of the gate 24 away from the field plate 26 to ensure full coverage of the gate 24 by the field plate end portion 261 in the second direction, thereby regulating, from multiple directions, the distribution of the electric field around the gate in the passive region that is close to the active region. Specifically, the terminating line of the first field plate end portion 261 is 2610, and the terminating line of the second field plate end portion 262 is 2620, it should be noted that, it is only necessary to ensure that at least one of the terminating line 2610 of the first field plate end portion 261 and/or the terminating line 2620 of the second field plate end portion 262 satisfies that full coverage on gate 24 in the second direction is realized, and optionally, the terminating line 2610 of the first field plate end portion 261 and the terminating line 2620 of the second field plate end portion 262 are simultaneously set to be located at a side of the gate 24 away from the field plate 26, which facilitates comprehensive regulation of the electric field around the gate of passive region at both sides of the active region, and also improves the stability and reliability of the field plate.

Further, it has been found that the terminating line of the field plate end portion 261 is located at a side of the gate 24 away from the field plate 26, and at the same time, it is also necessary to satisfy that the terminating line of the field plate end portion 261 is located at a side of the source 23 near the gate 24, and such a setup can avoid the problem of stress brought about by the process error between the field plate end portion of the passive region and the source during fabrication of the field plate, especially in a process structure in which the field plate body portion 260, field plate end portion 261 and field plate connecting portion 263 are integrally formed. Specifically, as shown in FIG. 2, the terminating line of the first field plate end portion 261 is 2610 and is located at a side of the gate 24 away from the field plate 26, and at the same time it satisfies that the terminating line 2610 is located at a side of the source 23 near the gate 24. Further, in order to ensure the reliability of the chip and the stability of the RF performance, the terminating line of the second field plate end portion 262 is 2620 and is located at a side of the gate 24 away from the field plate 26, and at the same time it satisfies that the terminating line 2620 is located at a side of the source 23 near the gate 24.

The above embodiments of the present disclosure, by setting a difference between the extending width of the field plate end portion 261 and that of the field plate body portion 260 to satisfy a certain relationship, improve the reliability and stability of the field plate in the passive region, as well as reduce the capacitance problem between the gate-source electrodes. Further, since the relative positions of the field plate 26 and the gate 24 are different, the terminating line of the field plate end portion 261 is set to be located at a side of the gate 24 away from the field plate 26, and at the same time, the terminating line of the field plate end portion 261 is set to be located at a side of the source 23 near to the gate 24, which can avoid the problem of stress of the structure surrounding the field plate end portion of the passive region and the source during fabrication of the field plate. It should be noted that, the shape of the first field plate end portion 261 and that of the second field plate end portion 262 may be the same or different, and the embodiments of the present disclosure do not impose any limitations on this.

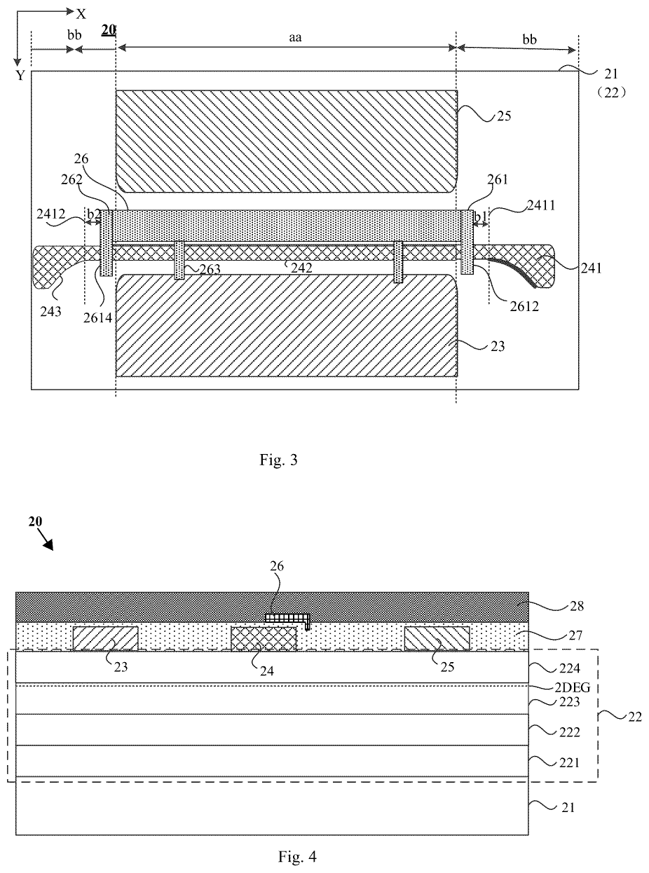

As shown in FIG. 3, in another implementation of the present disclosure, in the first direction, the gate 24 further includes a first end portion 241, an intermediate portion 242, a second end portion 243, wherein a majority of the intermediate portion 242 of the gate is located within the active region aa, the first end portion 241 of the gate and/or the second end portion 243 of the gate are located within the passive region bb, and a small portion of the intermediate portion 242 of the gate is located within the passive region. Setting an extending width of the first end portion 241/second end portion 243 of the gate, which are located at least within the passive region bb, in the second direction to be greater than an extending width of the intermediate portion 242 of the gate in the second direction, and setting the position of the boundary line (2411 and/or 2412) between the first end portion 241 and/or the second end portion 243 of the gate and the intermediate portion 242 of the gate to be located in the passive region, facilitate in regulating the distribution of electric field near the corner of the source and reducing breakdown.

Further, the first end portion 241 of the gate and/or the second end portion 243 of the gate are located in the passive region aa, wherein, a second boundary line of the field plate end portion 261 is located between the neighboring first end portion 241 of the gate and/or the second end portion 243 of the gate and the active region aa, or alternatively, a boundary line of the field plate 26 that extends in a first direction to the passive region bb is located between the active region aa and the first end portion 241 of the gate. It should be noted that, with regard to the second boundary line of the field plate end portion 261 is located between the neighboring first end portion 241 of the gate and/or the second end portion 243 of the gate and the active region aa, it may be that the second boundary line of the field plate end portion 261 is located at an arbitrary position between the boundary of the first end portion 241 of the gate and/or the second end portion 243 of the gate and the active region, that is to say, a projection of the field plate end portion 261 on the substrate and a projection of the first end portion 241 of the gate and/or the second end portion 243 of the gate on the substrate may overlap, and the projection of the field plate end portion 261 on the substrate and a projection of the intermediate portion 242 on the substrate may also overlap. In order to increase the process difficulty in the industrial manufacturing process, the second boundary line of the field plate end portion 261 may be located at a side, which is closer to the active region aa, of the boundary line 2411 between the first end portion 241 and the intermediate portion 242; such a design is beneficial to improve the distribution of electric field in the vicinity of the gate 24 near the active region aa within the passive region bb. In a first direction (X direction as shown in FIG. 3), the field plate 26 may start to extend from within the active region aa towards the second end portion 243 of the gate and extends into the passive region bb, that is, the boundary lines of the field plate 26 at both sides of the active region are both located within the passive region bb, and are located at a side, which is closer to the active region, of the boundary line between the first end portion 241 of the gate and/or the second end portion 243 of the gate and the intermediate portion; which facilitates improving the distribution of electric field at the edge of the whole active region, thereby improving the reliability and stability of the chip.

Further, it has been found that, as shown in FIG. 3, setting the boundary line (2411 and/or 2412) between the first end portion 241 and/or the second end portion 243 of the gate 24 and the intermediate portion 242 at a distance of b from the second boundary line of the adjacent field plate end portion, and satisfying b<3 μm, can improve the distribution of electric field at the end portion of the gate while decreasing the electrical resistance, and exemplarily, b may be 0.5 μm, 1 μm, 1.5 μm, 2 μm, 2.5 μm, etc. Setting a distance b1 of the second boundary line 2612 of the first field plate end portion 261 from the boundary line 2411 between the first end portion 241 of the gate and the intermediate portion 242 to be less than 3 μm may improve the distribution of electric field near the first end portion 241 of the gate. A distance b2 of the second boundary line 2614 of the second field plate end portion 262 from the boundary line 2412 between the second end portion 243 of the gate and the intermediate portion 242 may be set to be less than 3 μm. It should be noted that, b1 and b2 only need to satisfy that b1<3 μm and b2<3 μm, and the values of b1 and b2 may be different, but may be, in order to improve the overall reliability of the chip and the stability of the radio frequency performance, b1=b2 is set while satisfying b1<3 μm and b2<3 μm. When a distance of the boundary line (2411 and/or 2412) between the first end portion 241 and/or the second end portion 243 of the gate 24 and the intermediate portion 242 from the second boundary line of the adjacent field plate end portion is in the range of 0.1 μm to 1.5 μm, the distribution of electric field at the first end portion may be further effectively improved, thereby improving the reliability and stability of the chip.

In embodiments of the present disclosure, the shape of the field plate end portion may include at least one of rectangle, hammerhead, circle, semicircle, bulb, T, and L, and embodiments of the present disclosure have no limitation thereto.

As shown in FIG. 4, the multi-layer semiconductor layer 22 provided by embodiments of the present disclosure may include, in particular: a nucleation layer 221 located on the substrate 10, a buffer layer 222 located at a side of the nucleation layer 221 away from the substrate 21, a channel layer 223 located at a side of the buffer layer 222 away from the nucleation layer 221, a barrier layer 224 located at a side of the channel layer 223 away from the buffer layer 222, with the barrier layer 224 and channel layer 223 forming a heterojunction structure, and a 2DEG is formed at an interface of the heterojunction, and it may further include a cap layer located at a side of the barrier layer away from the substrate 21. The source 23, the gate 24, and the drain 25 are located at a side of the semiconductor layer away from the substrate 21, the field plate 26 is located near the gate 24 and at a side away from the substrate 21, a dielectric layer 27 may also be disposed between the field plate 26 and the gate 24, and a passivation layer 28 may also be disposed at the side of the field plate 26 away from the substrate 21.

Exemplarily, the materials of the nucleation layer 221 and the buffer layer 222 may be nitrides, specifically GaN or AIN or other nitrides, and the nucleation layer 221 and the buffer layer 222 may be used to match the material of the substrate base 10 and the epitaxial channel layer 223. The material of the channel layer 223 may be GaN or other semiconductor materials such as InAlN. The barrier layer 224 is located above the channel layer 223, and the material of the barrier layer 224 may be any semiconductor material capable of forming a heterojunction structure with the channel layer 223, including gallium-based or nitrogen-based compound semiconductor materials, such as InxAlyGazN1−x−y−z, wherein 0≤x≤1, 0≤y≤1, and 0≤z≤1. The channel layer 223 and the barrier layer 224 may form a semiconductor heterojunction structure, and high-concentration two-dimensional electron gas is formed at an interface of the channel layer 223 and the barrier layer 224.

The gallium nitride radio frequency device formed using the semiconductor device structure of the present disclosure can, on the premise of maintaining stable performance of the semiconductor device, increase the power and frequency of the gallium nitride radio frequency device while maintaining the reliability of the device, thus being more suitable for the field of high-frequency 5G communication.

It should be appreciated that embodiments of the present disclosure improve the output power of a semiconductor device from the perspective of its structural design. The semiconductor device includes, but is not limited to high-power gallium nitride High Electron Mobility Transistor (HEMT for short) operating in a high-voltage and high-current environment, transistor with a Silicon-On-Insulator (SOI for short) structure, gallium arsenide (GaAs)-based transistor as well as Metal-Oxide-Semiconductor Field-Effect Transistor (MOSFET for short), Metal-Semiconductor Field-Effect Transistor (MISFET for short), Double Heterojunction Field-Effect Transistor (DHFET for short), Junction Field-Effect Transistor (JFET for short), Metal-Semiconductor Field-Effect Transistor (MESFET for short), Metal-Semiconductor Heterojunction Field-Effect Transistor (MISHFET for short), or other field-effect transistors.

Based on a same inventive concept, embodiments of the present disclosure also provide a method of manufacturing a semiconductor device, including:
S110, providing a substrate.

Exemplarily, the material of the substrate may be Si, SiC, gallium nitride or sapphire, and may also be other materials suitable for growing gallium nitride. The substrate may be manufactured by an atmospheric pressure chemical vapor deposition method, a sub-normal pressure chemical vapor deposition method, a metal organic compound vapor deposition method, a low pressure chemical vapor deposition method, a high-density plasma chemical vapor deposition method, an ultra-high vacuum chemical vapor deposition method, a plasma-enhanced chemical vapor deposition method, a catalytic chemical vapor deposition method, a mixed physical chemical vapor deposition method, a fast thermal chemical vapor deposition method, a vapor phase epitaxy method, a pulsed laser deposition method, an atomic layer epitaxy method, a molecular beam epitaxy method, a sputtering method or an evaporation method.
S120, fabricating a multi-layer semiconductor layer at one side of the substrate.

Exemplarily, the multi-layer semiconductor layer is located at one side of the substrate, the multi-layer semiconductor layer may specifically be a semiconductor material from III-V group compound, and 2DEG is formed in the multi-layer semiconductor layer.
S130, fabricating a source, a gate and a drain at one side of the multi-layer semiconductor layer, and fabricating a dielectric layer on a side of the gate away from the substrate.

Exemplarily, the dielectric layer at least covers the gate to avoid a subsequent process resulting in the formation of a connection between the gate and the field plate; the dielectric layer may be fabricated with an overall coverage within the active region of the device, as well as within the extent that the gate extends to the passive region.
S140, fabricating a field plate near the gate located at a side of the dielectric layer away from the substrate, the field plate includes a field plate body portion, and at least one field plate end portion extending to a passive region, the field plate end portion extending from the field plate body portion toward the gate, and an extending width of the field plate end portion is greater than an extending width of the field plate body portion.

Exemplarily, wherein in the second direction (the Y direction as shown in the figure), the extending width of the field plate body portion 260 in the second direction is kept constant and maintained at a fixed value of D. The field plate end portion 261 is in zero contact with each of the source 23, the gate 24, and the drain 25, and the first field plate end portion 261 further includes a first boundary line near the active region, with the first boundary line being located within the passive region bb, this structural design not only can increase the reliability and stability of the field plate 26 but also can regulate the distribution of electric field of the passive region.

In an example process, a distance between the first boundary line of the field plate end portion and the adjacent active region aa is set to be d, which is less than or equal to 3 μm.

In an example process, a difference between the extending width of the field plate end portion 261 and that of the field plate body portion 260 satisfies L≥0.5*D, and the difference between the extending width of the field plate end portion 261 and that of the field plate body portion 260 satisfies L≤10*D.
S150, exposing a portion of the source before fabricating the field plate, and integrally forming the structure of the field plate in a same process step.

Exemplarily, exposing a portion of the source structure may be reserving most of the source structure during making the dielectric layer in step S130, that is, not depositing the dielectric layer in the reserved portion, or may be removing a portion of the dielectric layer above the source after the dielectric layer is deposited; which facilitates integrally forming the field plate body portion, the field plate end portion and the field plate connecting portion, and which may realize direct contact between the field plate connecting portion and the source, and zero contact between the field plate end portion and the source.

In summary, the semiconductor device and the method for manufacturing the same provided by embodiments of the present disclosure, by setting an extending width of the field plate end portion to be greater than an extending width of the field plate body portion in a second direction, and by setting a relationship satisfied by the difference between the extending width of the field plate end portion and that of the field plate body portion, improve the reliability and stability of the field plate, and by setting the distance relationship between the first boundary line of the field plate end portion and an adjacent active region, improve the distribution of electric field near the passive region and the active region, and reduce the gate-source capacitance. By ensuring that most of the source is exposed before fabricating the field plate, and then integrally forming the field plate body portion, the field plate end portion and the field plate connecting portion in a same process step, the process risk of that structure is reduced, thereby improving the reliability and stability of the device.

Note that the foregoing are merely example embodiments of the present disclosure and the technical principles utilized. It is appreciated by those skilled in the art that the present disclosure is not limited to the particular embodiments described herein, and various obvious changes, rearrangements, combinations and substitutions can be made by those skilled in the art without departing from the protection scope of the disclosure. Therefore, while the present disclosure has been described in greater detail through the foregoing embodiments, the present disclosure is not limited to the above embodiments, it may include further equivalent embodiments without departing from the idea of the present disclosure, and the scope of the present disclosure is defined by the scope of the appended claims.

1. A semiconductor device comprising an active region and a passive region surrounding the active region, the semiconductor device further comprising:
a substrate;
a multi-layer semiconductor layer located at one side of the substrate;
a source, a gate, and a drain located at a side of the multi-layer semiconductor layer opposite the substrate, the gate located between the source and the drain; and
a field plate located between the source and the drain, along a first direction, the field plate comprises a field plate body portion and a field plate end portion, at least one of the field plate end portions extending to the passive region, the first direction parallel to an extending direction of the source, the gate, and the drain;
wherein, an extending width of the field plate body portion in a second direction remains constant, at least one of the field plate end portions extending from the field plate body portion toward the gate in the second direction, an extending width of the at least one of the field plate end portions in the second direction is greater than the extending width of the field plate body portion, and the second direction is parallel to a direction from the source to the drain.

2. The semiconductor device according to claim 1, wherein the field plate end portion is in zero contact with each of the source, the gate, and the drain.

3. The semiconductor device according to claim 1, wherein, along the second direction and within the passive region, a projection of the field plate end portion on the substrate partially overlaps with a projection of the gate on the substrate, and wherein the projection of the field plate end portion on the substrate does not overlap with a projection of the source on the substrate.

4. The semiconductor device according to claim 1, wherein, along the first direction, the field plate end portion comprises a first boundary line and a second boundary line, wherein the second boundary line is located at a side of the first boundary line opposite the active region, and wherein the first boundary line and the second boundary line of at least one of the field plate end portions are both located within the passive region.

5. The semiconductor device according to claim 4, wherein a distance between the first boundary line of at least one of the field plate end portions and an adjacent active region is d, and wherein d≤5 μm is satisfied.

6. The semiconductor device according to claim 4, wherein the field plate end portion comprises a first field plate end portion and a second field plate end portion, wherein a distance between the first boundary line of the first field plate end portion and an adjacent active region is d1, wherein a distance between the first boundary line of the second field plate end portion and an adjacent active region is d2, and wherein d1=d2 is satisfied.

7. The semiconductor device according to claim 4, characterized in that, wherein the gate further comprises a first end portion of the gate, an intermediate portion of the gate, and a second end portion of the gate, wherein the first end portion of the gate and/or the second end portion of the gate is located within the passive region, wherein the second boundary line of the field plate end portion is located between an adjacent first end portion of the gate and/or an adjacent second end portion of the gate and the active region.

8. The semiconductor device according to claim 7, wherein the second boundary line of the field plate end portion is located at a side, which is closer to the active region, of a dividing line between the adjacent first end portion of the gate and/or the adjacent second end portion of the gate and the intermediate portion.

9. The semiconductor device according to claim 7, wherein a dividing line between the first end portion of the gate and/or the second end portion of the gate and the intermediate portion is at a distance of b from the second boundary line of the adjacent field plate end portion, and wherein b<3 μm is satisfied

10. The semiconductor device according to claim 9, wherein the field plate end portion comprises a first field plate end portion and a second field plate end portion, wherein the second boundary line of the first field plate end portion is at a distance of b1 from the dividing line between the adjacent first end portion of the gate and the intermediate portion, wherein the second boundary line of the second field plate end portion is at a distance of b2 from the dividing line between the adjacent second end portion of the gate and the intermediate portion, and wherein b1=b2 is satisfied.

11. The semiconductor device according to claim 1, wherein a difference between a width of the field plate end portion extending toward the gate and the extending width D of the field plate body portion is L, and wherein L 22 0.5*D is satisfied.

12. The semiconductor device according to claim 1, wherein the field plate end portion further comprises an extension terminating line, the extension terminating line is located at a side of the gate opposite the field plate.

13. The semiconductor device according to claim 1, wherein the field plate further comprises a field plate connecting portion, wherein the field plate connecting portion is located at the active region and extends from the field plate body toward the source until it contacts the source, and wherein the field plate body portion, the field plate end portion, and the field plate connecting portion are integrally formed.

14. A method of manufacturing a semiconductor device, for manufacturing the semiconductor device according to claim 1, the method comprising:
providing a substrate;
fabricating a multi-layer semiconductor layer at one side of the substrate;
fabricating a source, a gate, and a drain at a side of the multi-layer semiconductor layer opposite the substrate, the gate located between the source and the drain;
fabricating a dielectric layer at a side of the gate opposite the substrate; and
fabricating a field plate near the gate located at a side of the dielectric layer opposite the substrate, the field plate comprises a field plate body portion, and at least one field plate end portion extending to a passive region, the field plate end portion extending from the field plate body portion toward the gate, and an extending width of the field plate end portion is greater than an extending width of the field plate body portion.

15. The method of manufacturing a semiconductor device according to claim 14, wherein a portion of the source is exposed before fabricating the field plate, and wherein the field plate is formed integrally in a same process step.
